(19) United States
(12) Patent Application Publication
(10) Pub. No.: US 2025/0046606 A1
(43) Pub. Date: Feb. 6, 2025

(54) NON-THERMAL, LIQUID PHASE DEPOSITION OF THIN FILMS WITH VACUUM ULTRAVIOLET LAMPS

(71) Applicant: THE BOARD OF TRUSTEES OF THE UNIVERSITY OF ILLINOIS, Urbana, IL (US)

(72) Inventors: Jin-Hong KIM, Urbana, IL (US); Dane SIEVERS, Fisher, IL (US); Andrey MIRONOV, Urbana, IL (US); J. Gary EDEN, Champaign, IL (US); Sung-Jin PARK, Champaign, IL (US)

(21) Appl. No.: 18/718,694

(22) PCT Filed: Dec. 15, 2022
(86) PCT No.: PCT/US2022/053017

§ 371 Date: Jun. 11, 2024

Related U.S. Application Data
(60) Provisional application No. 63/290,339, filed on Dec. 16, 2021.

(51) Int. Cl. H01L 21/02; B05D 1/00; B05D 3/06

(52) U.S. Cl. CPC H01L 21/02282; B05D 1/005; B05D 3/067; H01L 21/02164; H01L 21/02186; H01L 21/02211; H01L 21/02216

(57) ABSTRACT

A method for non-thermal oxide deposition deposit a liquid-phase oxide or other dielectric precursor onto a substrate. The precursor is distributed uniformly. Electromagnetic radiation having a sufficient large photon energy so as to decompose at least partially the precursor(s), e.g., VUV or far UV radiation, is directed at the uniformly distributed precursor to at least partially decompose the precursor and deposit an oxide or other dielectric film on the substrate. The VUV/deep-UV radiation has a photon energy which exceeds that of at least one of the chemical bonds of the precursor(s). Deposition can be conducted at low temperatures, e.g. below ˜65° C., providing the ability for deposition on a wide variety of substrates including polymers and other flexible substrates.

### PRIORITY CLAIM AND REFERENCE TO RELATED APPLICATION

The application claims priority under 35 U.S.C. § 119 and all applicable statutes and treaties from prior U.S. provisional application Ser. No. 63/290,339, which was filed Dec. 16, 2021.

### BACKGROUND

Fields of the invention include photochemical growth of thin films from the liquid phase, oxide dielectric thin films, non-thermal growth of silicon dioxide films, carbon-based dielectric films, dielectric coatings, and electronic and photonic device fabrication.

### BACKGROUND

Thin oxide films are incorporated into virtually all electronic and photonic devices, and particularly those employing semiconductors. Silicon-dioxide (SiO₂), in particular, has long been among the most important materials in electronic device fabrication (primarily as passivation layers) but oxide films also have application as conductive or protective coatings on various surfaces. In the context of semiconductor device fabrication, the standard process for the deposition of oxide films (known as the “gold standard”) is expensive and slow because film growth is based on the chemical reaction of a gas or vapor with a hot surface (substrate). Such thermal reactions are the foundation for most commercial film growth processes, including chemical vapor deposition (CVD), plasma-enhanced chemical vapor deposition (PECVD), metal-organic chemical vapor deposition (MOCVD), and atomic layer deposition (ALD). In these and all other thermally-driven deposition or etching processes, the substrate temperature is the single most important process parameter because it dictates the rate at which the process proceeds.

The most commonly used dielectric material in semiconductor device fabrication is silicon dioxide (SiO₂). SiO₂ thin films are often grown or deposited by thermal oxidation which requires Si substrate temperatures above 1000° C., which is a slow process. The thermal nature of the oxide deposition process precludes growth on temperature-sensitive substrates and aggravates diffusional mixing among underlying layers on which the oxide might be grown. When compared to CVD, PECVD reduces the deposition temperature but the temperatures required for PECVD to achieve acceptable growth rates and film properties can still exceed the thermal limits of a number of materials adopted for emerging applications, such as wearable microelectronics and biodegradable devices. See, e.g., Hosseini, et al., “Biodegradable Materials for Sustainable Health Monitoring Devices,” ACS Appl Bio Mater., 2021, 4, 163-194.

Low temperature deposition of films can be achieved by physical vapor deposition (PVD), such as magnetron sputtering from high purity targets. However, the electrical and mechanical properties of as-deposited PVD films are often unsuitable for numerous applications and annealing the films at temperatures above 500° C. is generally required. Because the PVD process (including annealing) is also relatively slow, CVD film deposition processes remain the workhorse for electronic and photonic device foundries.

In this area, one advance is provided by Eden et al., WO 2020/081574, which describes an in-chamber VUV source that complements plasma by assisting ALD and CVD deposition processes. Arrays of microplasmas interact with the gaseous molecular precursor(s), resulting in the dissociation of the molecule but also the vibrational and electronic excitation of molecular fragments. The addition of VUV radiation enhances dissociation of the precursor(s) and can be beneficial in enhancing the mobility of atoms on the substrate surface. A drawback of all plasma-induced chemistry, however, is the breadth of the electron energies produced in the plasma. Because the electron energy distribution (EEDF) typically extends over more than 10 eV, the plasma produces a wide variety of atomic and molecular products. In other words, the plasma is not selective in the products generated, some of which are detrimental to depositing the desired film.

### SUMMARY OF THE INVENTION

A preferred embodiment provides a method for the non-thermal deposition of oxide- and other dielectric films onto a substrate from one or more liquid precursors. The deposition process is driven by photons which have sufficient energy to break the chemical bond(s) of interest in the precursor(s), such as vacuum ultraviolet (VUV) and/or far-ultraviolet (<230 nm) photons. Because the energy of the photons produced by the VUV/UV source can be well-defined (through the source central wavelength and bandwidth), the spectral properties of the source can be tailored to the precursor(s), and vice-versa, such that the desired chemical bonds within the precursor are those that are ruptured predominantly. That is, the photochemistry occurring within a thin liquid layer can be controlled so as to yield the intended solid thin film. Deposition can be conducted at low temperatures, e.g., as low as room temperature, providing the ability for deposition on a wide variety of substrates, including polymers and other flexible substrates. Furthermore, the invention provides for mixing two or more liquids to yield thin liquid films that, when irradiated with VUV/UV photons, produces solid films having the proper composition. Gases may also be “bubbled” through a liquid precursor prior to applying the liquid to a substrate. Transforming liquid films to thin solid films with photon sources enables the deposition temperature to be reduced significantly and films to be grown with compositions that are difficult to obtain with conventional deposition processes.

### BRIEF DESCRIPTION OF THE DRAWINGS

FIGS. 1A-F show a preferred method for the photochemical (non-thermal) deposition of dielectric films;

FIGS. 2A-2I show a preferred method for patterned non-thermal oxide deposition, and an example wafer fabricated by the preferred method;

FIGS. 3A-3E illustrate an experiment and data for oxide growth in accordance with the method of FIGS. 1A-1F;

FIGS. 4A-4F shows a series of SEM images of oxide on a trenched Si substrate and a photograph of oxide patterned on PET;

FIGS. 5A-5C illustrate a disassociation of TEOS liquid precursor and a nano template oxide growth method;

FIG. 6A-6F show images of patterned SiO₂ formed with a nano template of PS spheres;

FIGS. 7A-7D are data about the chemical composition analysis of SiO₂ thin film deposited on Si and PET substrates;

FIGS. 8A-8B provide data regarding dielectric breakdown voltage levels;

FIGS. 9A-9C are schematic diagrams showing the formation of stair-step profile oxide according to a preferred method of the invention;

FIGS. 10A-10C are schematic diagrams showing the formation of stair-step profile oxide according to a preferred method of the invention.

### DETAILED DESCRIPTION OF THE PREFERRED EMBODIMENTS

Preferred embodiment methods provide several advantages, as compared to conventional vapor deposition processes. Oxide deposition according to preferred methods has minimal impact on a fabrication process thermal budget. Oxide deposition can be conducted well below 120° C., e.g. at ˜25° C. (room temperature). Low temperature anneals, e.g., ˜200° C.-˜400° C. in studies conducted to date provided quality films with properties approaching that of traditional thermally grown films. Deposition is, therefore, enabled on a wide variety of thermally sensitive materials in addition to traditional wafers, including thermally sensitive materials used in wearable microelectronics and biodegradable devices.

Patterned deposition methods of the invention also can eliminate dry and wet etching steps used in conventional semiconductor fabrication processes. Such etching steps can be time consuming and can involve hazardous materials such as conventional photoresists.

In addition to using a simple, non-toxic photoresist (such as PMMA or another a polymer) for a pattern in a method of the invention, complex nano-structured 3D patterns are also enabled. As one example, experiments employed an in-situ deposition mask comprising a self-assembled hexagonal-closed-packed (HCP) monolayer of polystyrene spheres (PS). After oxide formation and the subsequent removal of the spheres, the deposited film reproduced an inverted, reduced dimension pattern. Such complex oxide patterns can be used for producing metamaterials, such as meta-reflectors. Complex patterns can also be used for producing optical filters such as 3D DBRs (Distributed Bragg Reflectors), Bayer filters, and microlens arrays, as well as cell sorting structures. Other nanostructured monolayers can be used, such as vertical nanowires and carbon nanotubes (CNTs). Such nanostructures can be of value, presuming that sufficient etch selectivity/solubility contrast/thermal stability is provided between the silicon oxide (for example) and the patterning/sacrificial monolayer.

Deposition methods of the invention also provide an advantage regarding planarization. Unlike conventional processes in which the growing film tends to reflect the morphology of the underlying layer (absent a separate planarization step), as-grown oxide films of the invention demonstrate increasing planarization as a function of the layer thickness. This can eliminate planarization steps required in some conventional thermal deposition processes.

Processing times can also be reduced greatly with deposition methods of the invention. Experiments have demonstrated growth rates for SiO₂ that are a factor of ˜30 larger than those associated with conventional thermal oxide growth techniques. Despite the growth rate, and in the absence of annealing, SiO₂ films grown by the present method at ˜25° C. (room temperature) demonstrate an breakdown electric field strength of ˜5 MV/cm. The scientific literature indicates that this value is a record for films grown at such low temperatures. A low temperature annealing step in the range of ˜200-400° C. improved the breakdown electric field strength to 7.5 MV/cm, which is close to the corresponding value of 8.5 MV/cm that was measured for SiO₂ films deposited by traditional thermal oxidation at 1000° C.

Deposition methods of the invention also present a scaling advantage. The formation of thin solid films by irradiating thin liquid films of the present methods allow for very large surface area film growth or deposition, far exceeding that of a wafer in a traditional semiconductor fabrication process. There is essentially no area limit, as the liquid precursor can readily be distributed (sprayed) over large surfaces which may be done outside of a sophisticated fabrication facility (one example is the deposition of an SiO₂ passivation layer onto a damaged or scratched part of a jet aircraft, or a surface of mechanical equipment such as a tractor, crane, or earth moving equipment that may quickly degrade if not passivated) and VUV light sources can be arrayed so as to decompose the liquid precursor and create the oxide or other dielectric layer. If the wavelength of the VUV source employed is sufficiently short that oxygen in the air begins to absorb the light (preventing it from reaching the desired surface), then the region from the lamp surface to the surface of interest can be flushed with nitrogen. In short, the value of this invention extends beyond the microelectronics and nanoelectronics and photonics industries to covering any surface that would benefit from not being exposed to atmospheric conditions.

Large area samples can be coated by thin dielectric (and other) films by spraying liquid precursor(s) onto a sample and exposing the liquid film distributed over the surface of interest by VUV/UV. This method allows depositing thin films outside of a deposition reactor, and offers protection for structures in marine environments (for example) or other harsh conditions in which applying robust film protection is difficult or not possible.

Nano and microparticles such as quantum dots, graphene, and carbon nanotubes can be mixed with liquid precursors which allows the deposition of oxide and other dielectric thin films with nanoparticles embedded in those film films. Glass with graphene inclusions has enhanced properties. Typically, such nano- and microparticles degrade/decompose at temperatures conventionally used for depositing thin oxide films, but the present method provides an efficient way to growth dielectrics with embedded nanoparticles.

Example experiments and tests have demonstrated patterned silicon dioxide (SiO₂) thin films deposited onto Si and PET (polyethylene terephthalate, a polymer) substrates at room temperature (300° K) and atmospheric pressure utilizing high average power flat vacuum ultraviolet (VUV) lamps emitting 172 nm radiation. The photon energy associated with λ=172 nm photons (hv=7.2 eV) is sufficient to dissociate tetraethyl orthosilicate (TEOS) in its liquid form and deposit high quality SiO₂ thin films onto an arbitrary substrate. Liquid TEOS solution was spin-coated onto the substrate while simultaneously illuminating it by the VUV radiation. The thickness of SiO₂ films can be controlled by the spin coater rotational velocity. Additionally, the thickness of the liquid layer on a surface can be controlled by ultrasound applied to that same surface.

In another experiment, in order to fabricate sub-400 nm diameter nanorings without the need for an etching process, TEOS was dispensed onto an in-situ deposition mask comprising a closed-packed monolayer of polystyrene spheres. After irradiation is completed and the microspheres are removed, an array of nanorings remains on the substrate. The process outcome does not depend critically on the diameter of the microspheres and example sphere diameters of 1-10 micrometers (μm) have been used to date. However, experimental results support that much smaller spheres (below 200 nm) in diameter, and much larger diameters (beyond 100 μm) will also work well. Arrays of such micro-rings can be utilized, for example, for micro-lens arrays, ring resonators, and discrete optical structures fabricated in-situ on devices at the wafer scale (e.g., LEDs/VCSELs), as well as micro-culture plates for bioengineering applications. Conventional techniques for forming structures in hard materials (oxides, metals, etc.), including techniques of molding, machining/milling (mechanical and ion-beam), abrasive blasting and laser ablation, are not suitable for making the precise nano-rings and other film geometries (thin slabs, hexagonal patterns, spiral, “star” patterns, etc.) that are fabricated quickly with the techniques described here.

In another experiment, metal oxide semiconductor capacitors (MOSCAPs) were fabricated to measure the electrical characteristics of SiO₂ thin films deposited by VUV illumination according to the present methods. The measured dielectric breakdown field (5 MV/cm) is within ˜30% of the dielectric breakdown strength of native oxides grown by the current standard thermal process at 1000° C. Since the entire fabrication process was performed at 300° K, SiO₂ thin films can be also deposited on PET and other low thermal budget substrates, permitting use of the method in fabricating flexible electronic devices on any polymer, mica, and other flexible and/or temperature-sensitive substrate. Additionally, the chemical composition of the deposited SiO₂ thin films on both PET and Si substrates were analyzed by Rutherford Back Scattering (RBS) and X-ray Photoelectron Spectroscopy (XPS) to verify the chemical composition and stoichiometry of the films.

SiO₂ and other oxides can be deposited from other liquid precursors. Other SiO₂ liquid precursors (which require a separate oxygen source during deposition) include siloxanes, e.g., silicone oil and PDMS (polydimethylsiloxane): CH₃[Si(CH₃)₂O]ₙSi(CH₃)₃. Additional SiO₂ liquid precursors include silazanes, e.g., HMDS (hexamethyldisilazane): [(CH₃)₃Si]₂NH. For TiO₂, liquid precursors include titanium isopropoxides (Ti(OPrⁱ)₃(OCH₂CH₂NMe₂) and Ti(OPrⁱ)₂(OCH₂CH₂NMe₂)₂), titanium ethoxide (Ti₄(OCH₂CH₃)₁₆), titanium methoxide (Ti(OMe)₄) and Tetrakis(dimethylamido)titanium: Ti(NMe₂)₄ where “Me” represents a methyl ligand. Liquid precursors for other oxides, e.g., vanadium dioxide and hafnium dioxide, are available in the literature. Therefore, thin films of TiO₂ and the oxides of hafnium may also be deposited by the deposition techniques described here and those skilled in the art will immediately recognize other metal oxide films that are candidates for these processes. Additional exemplary experiments have shown that DC-710 (silicon oil) decomposes to form a vitreous solid film, and PDMS decomposes to form a brittle transparent oxide on the surface that cracks when flexed. Deposition of TiO₂ from tetraethyl orthotitanate and metal oxides from metal ac-acs (acetyl acetylates)—including molybdenum oxide and chromium oxide have all been deposited at 25° C.

The composition and structure of the solid thin films available with the present methods can be expanded by mixing liquid precursors prior to applying the precursor to a surface. For example, mixing TEOS with carbon tetrachloride or carbonic acid in differing ratios allows for SiCO₂ films to be produced, and the relative contribution of the amount of carbon in the film can be controlled precisely. Similarly, “bubbling” gases and vapors through a specific liquid precursor will allow for films having previously unavailable compositions, or film structures that are stable only at reduced temperatures, to be fabricated. One intent of this invention is to drive the surface liquid/surface chemistry far from thermal equilibrium so as to realize unique materials, or to deposit conventional materials at significantly reduced temperatures.

Low temperature, atmospheric pressure, high deposition rate silicon dioxide films deposited from a bulk liquid precursor according to the invention can fundamentally change integrated circuit multi-level metal process flows. Present methods can eliminate thermal budget impact and reduce the need for chemo-mechanical planarization (CMP) of inter-level dielectrics (ILDs). Selective area deposition can be achieved utilizing in-situ organic polymer templates, eliminating the need for a via etch. Methods of the invention further provide a simple fabrication method for complex geometries such as air-bridges, voids, and retrograde sidewall profiles using in-situ patterned organic polymer deposition masks. As examples, experiments have demonstrated selective area deposition using standard G- and H-line photoresists. By means of a patterned organic resist layer which is deposited with a thickness less than the deposited oxide thickness, the encapsulated pattern can be dissolved to leave voids or bridges. Additionally, 3D photolithography resulting from multiple exposures can create stair-step profiles that will result in ‘retro-grade’ silicon oxide sidewalls.

Preferred embodiments of the invention will now be discussed with respect to the drawings and experiments used to demonstrate the invention. The drawings may include schematic representations, which will be understood by artisans in view of the general knowledge in the art and the description that follows. Features may be exaggerated in the drawings for emphasis, and features may not be to scale.

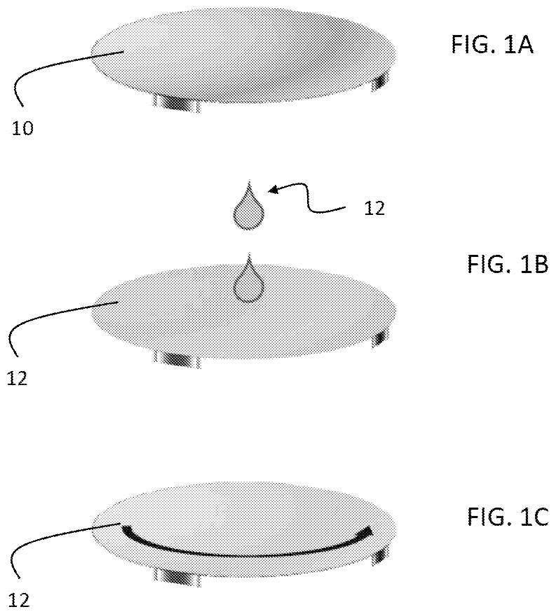

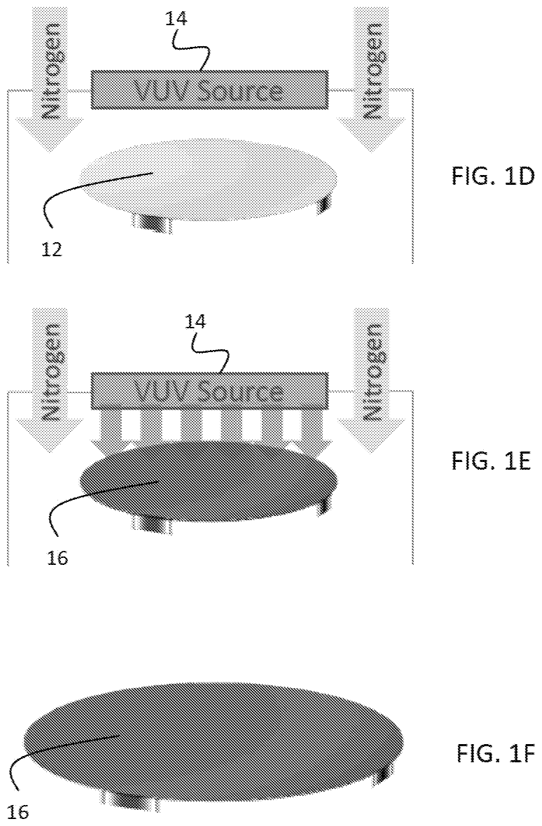

FIGS. 1A-F show a preferred method for non-thermal oxide deposition. In FIG. 1A, a substrate 10 is provided. The substrate 10 can be, for example, a silicon wafer. However, metals, glass, polymers and many other substrates can be used as the method provides very low growth temperatures that enable a wide variety of substrates. PET is another substrate that was tested, and the bonding mechanism supports a wide variety of substrates such as copper, glass, and polystyrene. In FIG. 1B, a liquid precursor 12 is applied to the substrate and then is uniformly distributed in FIG. 1C, e.g., by spinning the substrate 10. In FIGS. 1D and 1E, the liquid precursor 12 is irradiated from a VUV source 14, which decomposes the precursor and forms a uniform oxide layer 16 in FIG. 1F. Other reaction products (characterized as H, OH, H₂O, and CH₃ with an RGA) are volatile and leave the growing solid film.

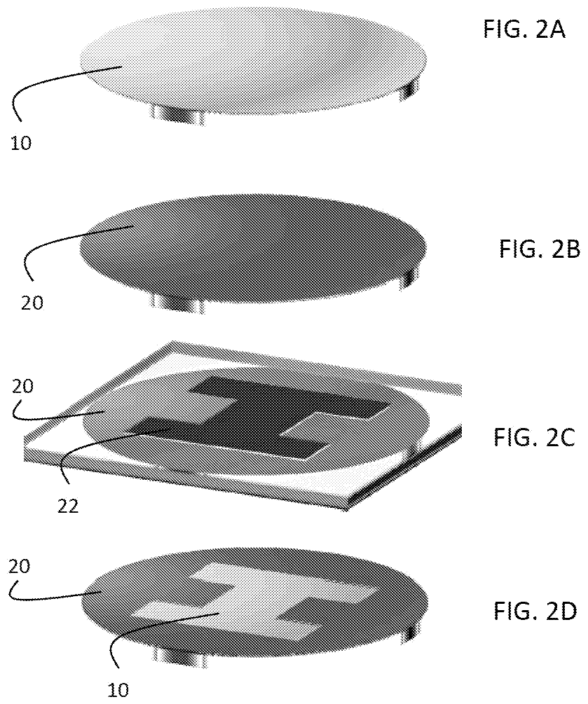

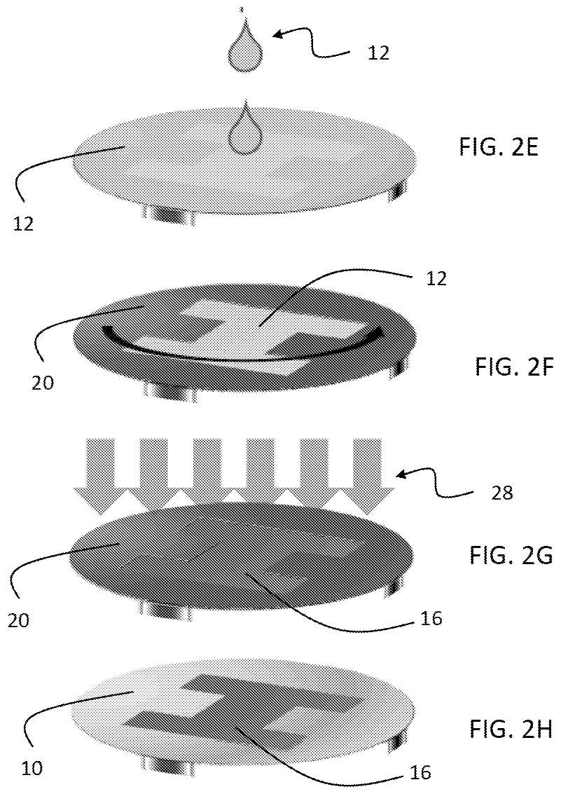

FIGS. 2A-2H show a preferred method for patterned non-thermal oxide deposition. A substrate 10 is provided in FIG. 2A, and photoresist 20 is deposited in FIG. 2B. In FIG. 2C, the photoresist 20 is exposed in a pattern 22. In FIG. 2D, development of the exposed pattern 22 exposes the substrate 10 in the pattern 22. FIG. 2E illustrates the application of liquid precursor 12, and FIG. 2F shows the spinning platform to evenly distribute the liquid precursor 12 over the substrate 10. Irradiation with VUV “light” (emission) decomposes the precursor to deposit oxide 16 in the pattern 22, as shown in FIG. 2G. Removal of photoresist in FIG. 2H leaves the patterned oxide 16 on the substrate 10. A 2 inch diameter sample Si wafer with deposited thin SiO₂ film using method described in FIG. 2A-2H is shown in FIG. 2I.

Spinning distribution of the liquid precursor as shown in FIG. 1C or 2F is one option, but other options exist for the distribution of the liquid precursor. Spinning is very effective in a deposition reactor, for example, for uniform distribution of the liquid precursor. An alternative to spinning is ultrasound to establish a flat surface or, if desired, sinusoidal patterns on the surface of a liquid precursor layer. Such patterns are useful, for example, to form optical waveguides or diffraction gratings. Deposition and distribution can also be conducted outside of a deposition reactor, which is especially useful for large surface area deposition or deposition on very large or complex, 3D surfaces via spraying of the precursor with a nozzle that provides a uniform spray pattern. For example, an experiment demonstrated spray coating of a 5″ diameter Si wafer with a thin SiO₂ film deposited on it, followed by photodecomposition of the precursor using a large area, 100 mm×100 mm VUV lamp. Larger surface areas can be covered, and objects encapsulated, using large microplasma lamps, e.g., a 200 mm×200 mm VUV lamp, or “tiling” a number of smaller lamps to realize a surface area of 1 m² or larger of radiating lamp area.

In other experiments demonstrating the methods of FIGS. 1A-2H in a reactor with smaller, e.g., 2″ wafers, a microplasma VUV (172 nm) flat lamp has been used to deposit SiO₂ thin films by dissociating TEOS precursor at atmospheric pressure and at 300 K (i.e., room temperature). The flat lamp is available from Eden Park Illumination of Champaign, IL and is described in Park et al., “25 W of average power at 172 nm in the vacuum ultraviolet from flat, efficient lamps driven by interlaced arrays of microcavity plasmas,” APL Photonics 2, 041302 (2017). Other VUV irradiation wavelengths can be used. Any photon having an energy exceeding the energy of the desired chemical bond in the precursor is expected to perform as well. As an example, 172 nm=7.2 eV=694.7 kJ/mol, which exceeds the bond energies of most organic bonds except C≡C, C≡N, and N≡N. Lamps emitting at several wavelengths of interest (including 149 nm and 129 nm) are under development, and these also exceed the energies of virtually all chemical bonds.

Direct photodissociation of a TEOS film while spinning on a substrate using high energy VUV photons (>7.2 eV) to deposit a thin layer was investigated. This excimer (Xe₂) lamp exhibits high radiation power with large area coverage and spatially-uniform intensity. This efficient radiation source is based on arrays of low temperature and non-equilibrium microplasmas, and the electron temperature of the microplasmas lies in the 2-5 eV interval. An advantage of using excimer lamps is that these molecules are produced efficiently in the microplasma arrays from which the lamp is constituted. Additionally, the flat form factor and diffuse glow of the lamp provide uniform treatment over the full area of the lamp. Therefore, the deposition area can be easily scaled along with the flat lamp size at given intensities. Preferred conditions to ensure deposition include the following.

The atmosphere used is selected to transmit (not absorb) the photons, e.g. (N₂ or Ar for 172 nm). The atmosphere should also be dry to prevent hydration reactions. The substrate should be clean to prevent compromising the electronic, mechanical, optical, or chemical integrity of the deposited film. This is not as stringent of a requirement for less demanding applications, and the demonstrated films can be deposited under less-than-ideal conditions (minimal cleaning of substrate, performed in a non-clean area, dispensed from disposable pipettes) when that concern is not an issue. The precursor should be sufficiently pure to satisfy the necessary composition of the film formed. That is, low-purity precursors may be acceptable in applications in which the VUV lamp breaks specific bonds such that the impurity is removed as a volatile product. Substrate surface termination/surface states are not believed to play a significant role in the deposition process as the high energy photons appear to perform a ‘cleaning’ action at the surface.

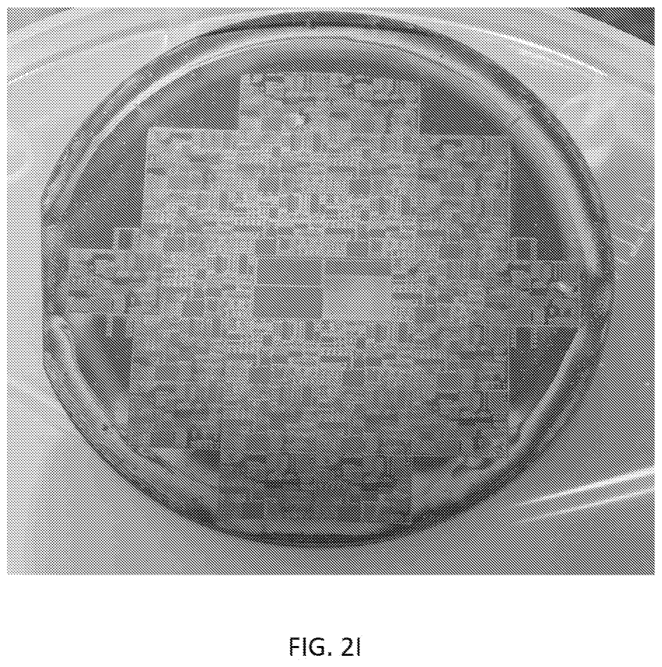

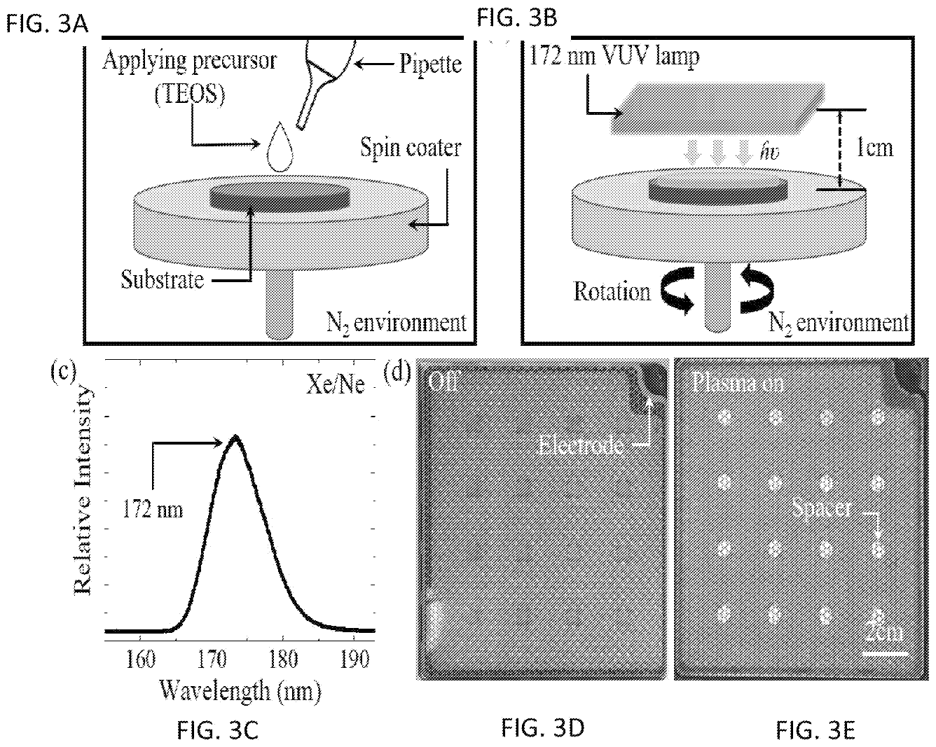

FIGS. 3A-3E illustrate an experiment and data for oxide growth in accordance with the method of FIGS. 1A-1F. The substrate was a p-type (100) silicon wafer. An RCA cleaning process removed inorganic and organic surface contaminants. During cleaning, the wafer was immersed in 10% hydrofluoric acid for ˜3 minutes to remove the native oxide and dried in a nitrogen flow. The deposition of an SiO₂ thin film was performed in a simple N₂ purged reactor equipped with a 172 nm VUV excimer lamp and spin coater, as represented in FIG. 3A. TEOS was applied with a pipette onto the substrate and VUV illuminated while spinning as shown in FIG. 3B. The rotation velocity was chosen depending on the film thickness. Typical rotational velocities can range from 100 to several thousand rpm (a similar range to that used when spinning on photoresists). Thinner films were deposited with higher rotation frequencies and thicker films with lower rotation frequencies. A 1 μm (one micrometer)-thick SiO₂ film, for example, typically required a spin coater frequency of 100-200 rpm.

The substrate was placed 1-1.5 cm from the VUV lamp, a distance chosen to maximize the spatial uniformity of the incident VUV light at the surface of the substrate. The optimal distance for uniform power distribution is currently ˜1.5 cm but this value will undoubtedly change as the optical source characteristics and the specific precursor(s) are altered. However, experiments over a range of several centimeters have also demonstrated success, and a 75 mm (7.5 cm) working distance is also expected to function well. The minimum distance is selected so as to avoid the deposition of a thin film on the window of the VUV lamp.

The reactor was purged with research-grade N₂ at a flow rate of 10 slm so as to maintain one atmosphere of pressure in the reactor. Filling the reactor (i.e., processing chamber) with one atmosphere of nitrogen allows for the elimination of vacuum systems which are invariably required for traditional industrial microelectronic processing. Because 172 nm radiation is absorbed strongly by oxygen but not nitrogen, this oxide film process can be conducted at room pressure (one atmosphere). After the target substrate was irradiated by the 172 nm (VUV) photons, the SiO₂ film samples were analyzed by scanning electron microscopy (SEM: 4800 Hitachi), Rutherford backscattering spectrometry (RBS), and X-ray photoelectron spectroscopy (XPS: Axis ULTRA, Kratos). In order to determine several electrical characteristics of these oxide films, metal oxide semiconductor capacitors (known as MOSCAPs) were fabricated and characterized. Films of aluminum and gold, deposited by an electron beam evaporator, served as the metal contacts for the MOSCAP device analysis and the results of the MOSCAP studies will be discussed later. One-half of one milliliter of TEOS was applied to the substrate with a pipette to cover the entire substrate area (2×2 cm), and the VUV lamp illuminated the substrate while the Si(100) substrate was spinning at a predetermined speed, as illustrated in FIG. 3B. FIG. 3C shows the emission spectrum of the VUV lamp which has been used in SiO₂ thin film deposition experiments. FIGS. 3D and 3E show a 172 nm microplasma VUV lamp (50×50 mm and 100×100 mm, Eden Park Illumination, Inc. Champaign, IL, USA) in operation. The lamp intensity for most of the tests described here was 13 mW/cm² when the lamp was driven with a ˜20-30 kHz, 3 kV power supply. However, it must be noted that these VUV lamps are capable of emission intensities beyond 300 mW/cm², given the proper power supply. Therefore, the TEOS layer irradiation times required for the deposition of an SiO₂ film of a given thickness can be shortened considerably.

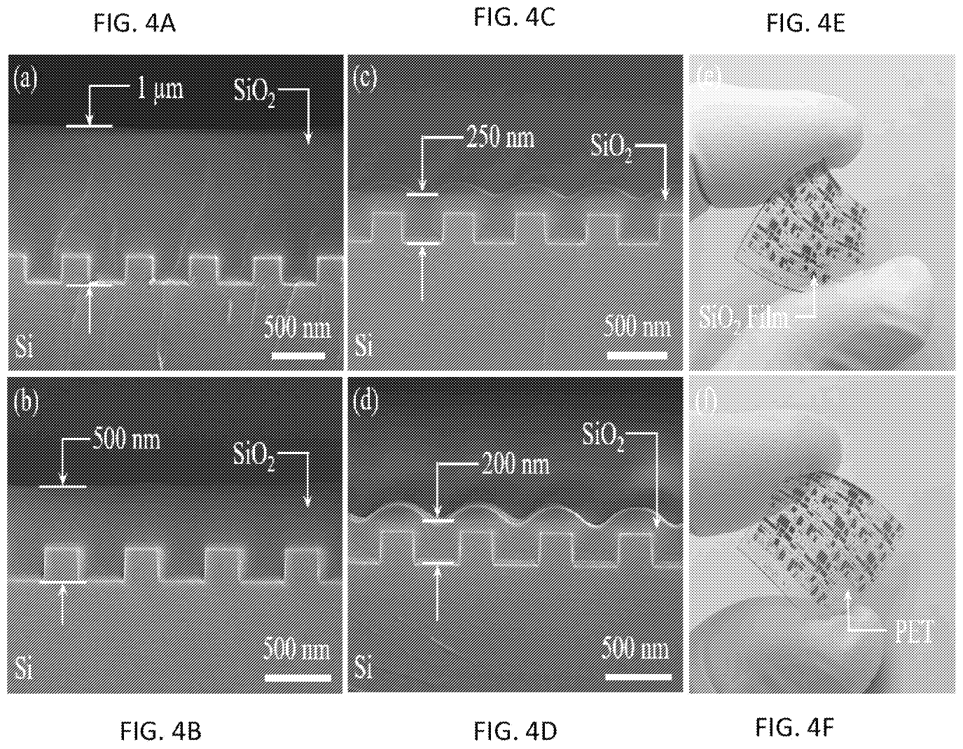

FIGS. 4A-4F shows a series of SEM images of oxide films on a Si substrate patterned in the form of a series of trenches, as well as photographs of silicon dioxide patterned onto the polymer PET. All of the films shown were deposited at room temperature (300 K). As shown in FIG. 4A, 1 μm-thick SiO₂ films were deposited onto a Si (100) substrate after only 20 minutes of VUV illumination. We note that the growth of an SiO₂ thin film only 40 nm in thickness by the conventional thermal oxidation process (known as the industrial “gold standard”) requires approximately 25 minutes when the substrate temperature is 1000° C. and the reactor is filled with pure oxygen. Consequently, the growth rate for SiO₂ thin film from TEOS and 172 nm VUV illumination is approximately 30 times faster than that for thermal oxidation. Another asset of the process described here is that oxide film thicknesses in the range of approximately 200 nm to 1 μm can be controlled with the same test arrangement by simply changing the speed at which the substrate is rotated. However, with much thicker films (>several μm), it may be necessary to deposit several thinner films so as to maintain the quality of the total (composite) oxide film.

Another interesting aspect of the film deposition method described here is that the surface of the film can be modulated in the form of a sinusoid, as shown in FIGS. 4C and 4D. This effect is believed to be due to the synergy between the rate of rotation of the substrate and the viscosity of the liquid layer immediately prior to the conversion of the liquid layer into a solid film by the process of 172 nm photolysis of TEOS or other precursor. That is, the liquid layer and spinning substrate establish a sinusoidally-varying surface profile which is “frozen” into a solid by the VUV lamp. Sinusoidal surfaces or films are difficult or impossible to fabricate with traditional microelectronics processing methods, and yet this geometry is optimal for a variety of optical and optomechanical or electromechanical components such as optical diffraction gratings. Furthermore, it has been shown in the past that the fabrication silicon and other semiconductor films in a “corrugated” or sinusoidal form may be advantageous in relieving stress in the semiconductor film. Therefore, a new generation of optical and electronic devices incorporating optically- or electrically-active films grown onto metal oxide films having sinusoidally varying surfaces is provided through present methods. Specifically, after formation of the oxide or dielectric film according to the invention, depositing an optically- or electrically-active thin film, such as GaN, Ga₂O₃, Si, Ge, or GaAs, onto the oxide or other dielectric film forms a unique device structure. Because the crystalline lattice structure of the top film will be alternately compressed or “stretched” by the ridges and valleys of the underlying oxide film, electronic and optical effects not obtainable with conventional flat films will be observed in the top film which could be, for example, Si, Ga₂O₃ or GaN. Finally, flexible microelectronics can be fabricated with SiO₂ thin films deposited onto PET substrate (or other flexible materials as illustrated in FIGS. 4E and 4F. This is possible because the SiO₂ deposition temperature, for example, can be much lower than ˜65° C., the glass transition temperature of PET.

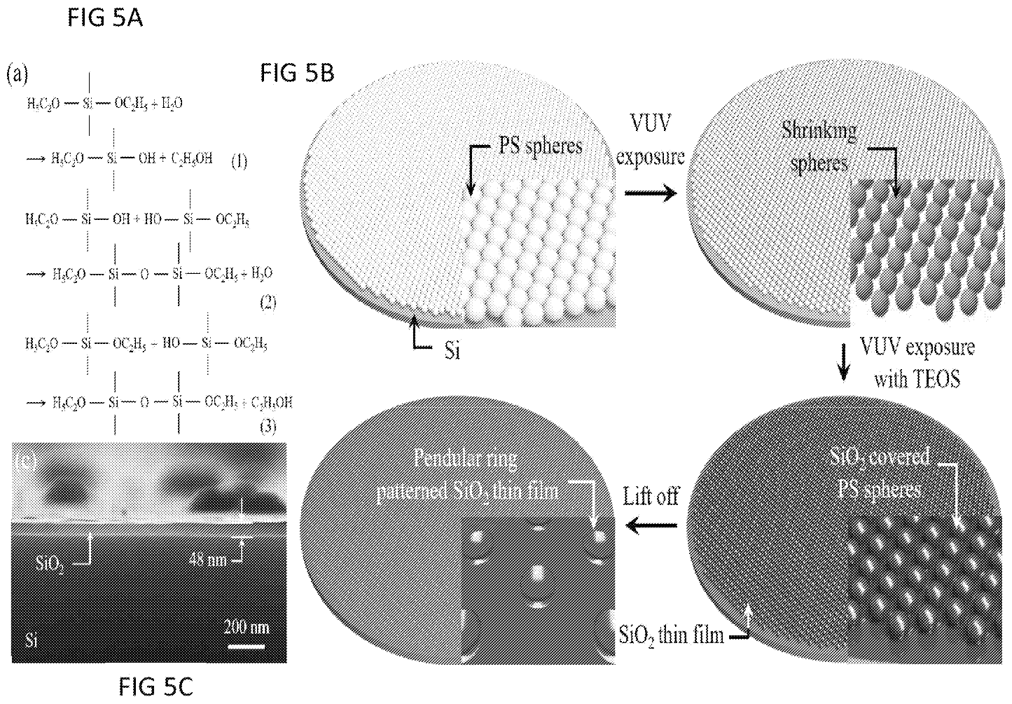

FIG. 5A shows the apparent mechanisms by which TEOS is dissociated by photolysis at 172 nm, resulting in the formation of a Si—O bond. Further study is necessary to determine the specific photochemical route by which SiO₂ is formed but the process illustrated in FIG. 5A is one possibility. FIG. 5B is a schematic diagram illustrating the deposition of 400-500 nm diameter SiO₂ nanorings by employing large arrays of ˜1 μm diameter polystyrene spheres to serve as a mask. After dispensing TEOS onto the substrate and array of polystyrene spheres, this assembly is illuminated by the VUV lamp and the spheres are subsequently removed. FIG. 5C is an image of the ˜48 nm-thick SiO₂ nanorings deposited on a Si substrate by this patterning process. It must be emphasized that the diameter of the rings can be controlled by the diameter of the microspheres, combined with conventional lift-off steps.

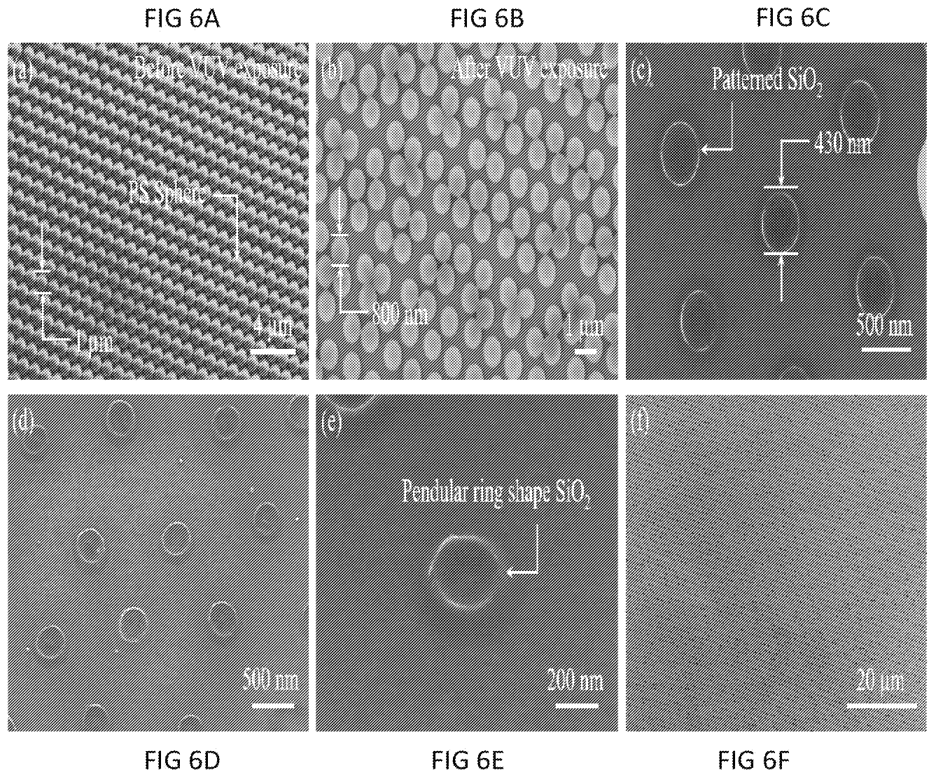

FIGS. 6A-6F show images of SiO₂ rings formed with a template (effectively a mask) of polymer spheres. FIG. 6A shows a monolayer of 1 μm diameter spheres on a Si substrate, and FIG. 6B shows the reduction in the diameter of the polymer spheres after VUV exposure because the VUV radiation photoablates a portion of each polymer sphere. FIG. 6C shows a top-view of the nanorings that one observes after lift-off of the microspheres, and FIGS. 6D-6F are more images of the oxide nanorings that can be fabricated by this method.

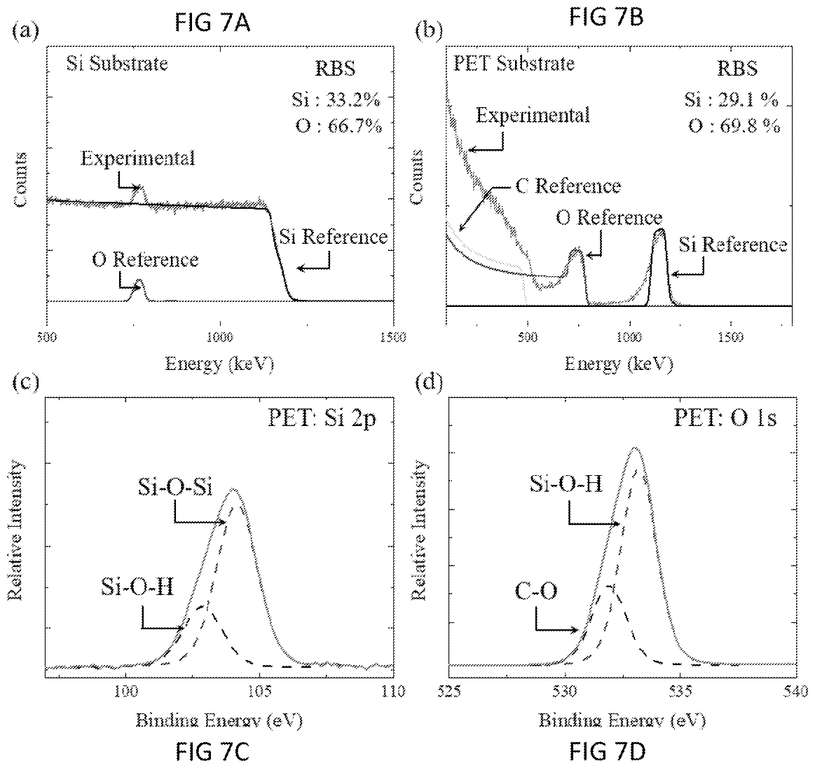

FIGS. 7A-7D provide data about the chemical composition analysis of SiO₂ thin films deposited onto Si and PET substrates. FIG. 7A is an RBS spectrum of SiO₂ deposited at 300 K onto a Si(100) substrate. FIG. 7D is an RBS spectrum of SiO₂ deposited at 300 K onto a PET substrate. Black, blue, and green curves represent data for Si, O, and C, respectively. FIGS. 7C and 7D are XPS spectra recorded for an SiO₂ thin film deposited onto a PET (polymer) substrate. The experimental curves represent the measured data, and the reference curves are simulated from known atomic standards. RBS was employed to determine the stoichiometry of the films, and FIG. 7A is an RBS spectrum for a ˜50 nm-thick film deposited at 300 K. Over the 300-1200 keV interval, the experimental data match the theoretical spectrum constructed from atomic O and Si references. The average O/Si ratio is found to be 2.00±0.10, where the uncertainty represents ±1 σ in the measurements. The simulation curves calculated by the experimental parameters are in good agreement with the experimental RBS spectra, indicating that the composition of the deposited SiO₂ film is stoichiometric (i.e., SiO₂).

The core level XPS data for the Si 2p and O 1s peaks also revealed information about the surface chemistry of the as-deposited SiO₂ thin films, as illustrated in FIGS. 7C and 7D. The two main peaks with relatively high intensity were observed at binding energies at ˜102 eV and 104 eV in FIG. 7C which correspond to Si—O—H and Si—O—Si. These indicate that the SiO₂ film is coated on the surface with silanol groups. The O 1s peak of FIG. 7D indicates that the amount of residual carbon in the films can be tuned by the selection of precursor(s) (i.e., low or high carbon to other element ratios). This can be exploited for matching the film composition to specific applications (k-modulated films).

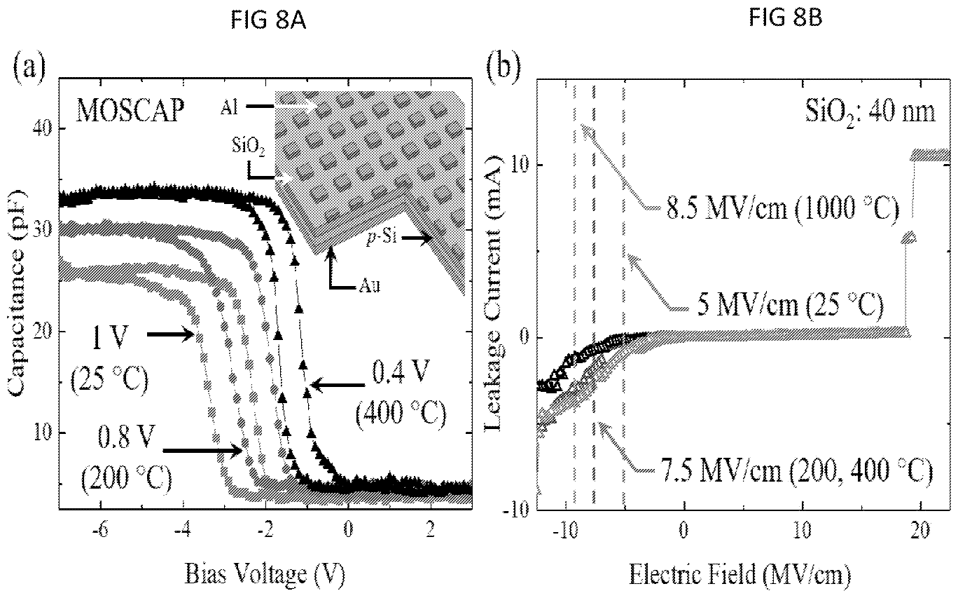

FIGS. 8A-8B provide data regarding dielectric breakdown strengths of the deposited SiO₂ films. FIG. 8A shows capacitance-voltage (C-V) and dielectric breakdown data for p-Si/SiO₂ MOSCAPs with a 40 nm thick oxide film deposited at 25° C., and 40 nm-thick oxide films deposited at 25° C. followed by post-annealing at 200° C. and 400° C. FIG. 8B presents data illustrating the dependence of the MOSCAP leakage current on the breakdown electric field strength. For the sake of comparison, MOSCAPs identical to that for the 25° C.-grown SiO₂ film except for the oxide film processing are also shown in FIG. 8B. Specifically, the performance of MOSCAPs fabricated with films deposited at 25° C. but post-processed at 200° C. and 400° C. are also shown. The “benchmark” breakdown electric field strength for a 40 nm-thick SiO₂ thin film grown by thermal oxidation at 1000° C. is represented in FIG. 8B by the dashed line.

The inset of FIG. 8A is an illustration of the capacitor structure fabricated with a 40 nm-thick SiO₂ film deposited onto a Si substrate. Square Al ohmic contacts and a gold contact film were evaporated to complete the devices. Capacitance-voltage (C-V) characteristics, recorded at 1 MHz, demonstrate that the width of the hysteresis of the C-V curve for films as-deposited at 25° C., for example, is ˜1 V, implying that a low level of carbon impurities (or traps at the Al electrode) have been incorporated into the oxide film. When the as-deposited films at 25° C. were post-annealed at 200° C. and 400° C., however, the hysteresis width decreased from ˜1 V to 0.4 V, indicating that the trap charge caused by carbon impurities or the ohmic contact at the Al/SiO₂ interface had been decreased significantly.

Electrical breakdown data corroborate this conclusion. As shown by FIG. 8B (mentioned earlier), the breakdown electric field strengths of the as-deposited (25° C.) and post-annealed (200/400° C.) films are calculated to be 5 and 7.5 MV/cm, respectively. In order to establish a reference for the breakdown field strength of SiO₂ thin films deposited by the VUV lamp, 40 nm-thick SiO₂ thin films were deposited on a Si substrate by thermal oxidation at 1000° C. The breakdown electric field strength of the thermally-grown oxide film was found to be ˜8.5 MV/cm which is 70% higher than that for the film deposited by VUV at 25° C. (5 MV/cm). Despite the lower value for the film grown at room temperature and not annealed, this value is more than adequate for many electronic and photonic devices. Although the electrical characteristics of the demonstrated deposited SiO₂ films are slightly inferior to those grown by thermal oxidation at very high temperatures, the low deposition temperature and high deposition rate for the films described here are quite attractive for applications such as masking films in microelectronics and bioengineering applications, and for increasing the speed and reducing the costs of the fabrication of traditional semiconductor devices. Of equal importance to the future of semiconductor device manufacturing is that the deposition of metal oxide films at greatly reduced temperatures lowers the overall thermal budget impact, as compared to other deposition techniques.

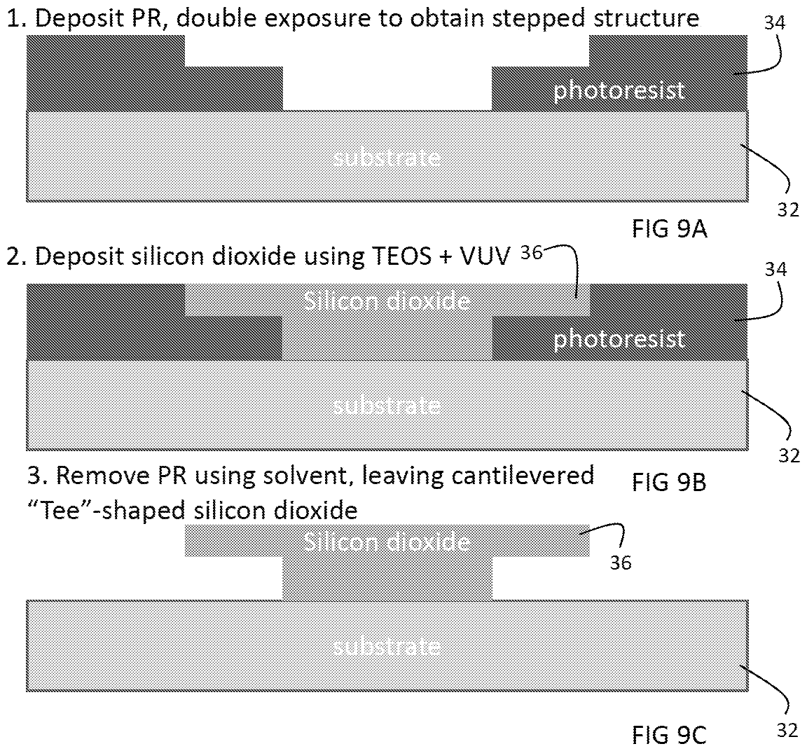

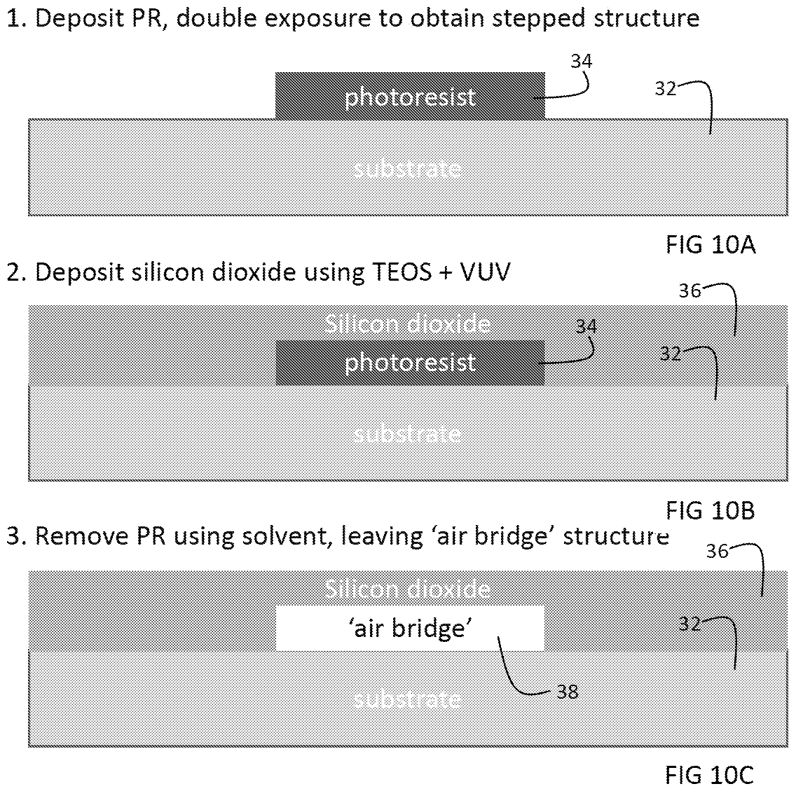

As mentioned above, the oxide deposition process of the invention can be used with other photoresist patterns to create structures such as step profiles and air bridges. This is shown in FIGS. 9A-9C and 10A-10C. This liquid phase, photochemical (non-thermal) deposition process readily creates such structures with reduced complexity during the fabrication process. In FIGS. 9A-9C and FIG. 10A-10C, a substrate 32 is patterned with photoresist 34 by conventional techniques. Oxide is then deposited according to the above methods, and the pattern of the photoresist dictates the eventual pattern of the oxide. With the stepped pattern photoresist of FIGS. 9A-9B, a cantilevered “T” shaped oxide film 36 is formed. With the simple mesa pattern of photoresist of FIGS. 10A-10B, an air bridge 38 is formed.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A method for non-thermal metal-oxide or other dielectric film deposition, comprising:
depositing a liquid-phase precursor of the oxide or other dielectric onto a substrate;
distributing the liquid-phase precursor uniformly to form a uniformly distributed liquid-phase precursor layer; and
directing radiation having a photon energy sufficient to decompose the liquid-phase precursor of the uniformly distributed liquid-phase precursor layer, yielding an oxide or other dielectric film on the substrate.

2. The method of claim 1, wherein the radiation comprises vacuum ultraviolet (VUV) or far-UV radiation (wavelength at or below approximately 230 nm).

3. The method of claim 1, wherein the substrate comprises a flat surface and distributing the liquid-phase precursor comprises spinning the flat surface.

4. The method of claim 3, comprising a preliminary step of creating a patterned mask on the surface, wherein the depositing deposits the liquid-phase precursor into the patterned mask, and further comprising removing the mask after the oxide film is deposited.

5. The method of claim 1, conducted at a temperature below 120° C.

6. The method of claim 5, conducted at a temperature in the range of ˜20° C.-120° C.

7. The method of claim 1, wherein the directing is conducted in a N₂ purged reactor equipped with one or more 172 nm VUV excimer lamps.

8. The method of claim 1, wherein the liquid-phase precursor is tetraethyl orthosilicate (TEOS) and the oxide film is SiO₂.

9. The method of claim 1, wherein the liquid-phase precursor is a siloxane and the oxide film is SiO₂.

10. The method of claim 9, wherein the siloxane is one of silicone oil and PDMS (polydimethylsiloxane): CH₃[Si(CH₃)₂O]ₙSi(CH₃)₃.

11. The method of claim 1, comprising providing oxygen during the directing wherein the liquid-phase precursor is a silazane and the oxide film is SiO₂.

12. The method of claim 11, wherein the silazane is HMDS (hexamethyldisilazane): [(CH₃)₃Si]₂NH.

13. The method of any of claim 1, wherein the liquid-phase precursor is titanium isopropoxide and the oxide film is TiO₂.

14. The method of claim 13, wherein the liquid-phase precursor is one of Ti(OPrⁱ)₃(OCH₂CH₂NMe₂) and Ti(OPrⁱ)₂(OCH₂CH₂NMe₂)₂.

15. The method of claim 1, wherein the liquid-phase precursor is titanium ethoxide: Ti₄(OCH₂CH₃)₁₆ and the oxide film is TiO₂.

16. The method of claim 1, wherein the liquid-phase precursor is titanium ethoxide Ti₄(OCH₂CH₃)₁₆ and the oxide film is TiO₂.

17. The method of claim 1, wherein the liquid-phase precursor is titanium methoxide: Ti(OMe)₄ and the oxide film is TiO₂.

18. The method of claim 1, wherein the liquid-phase precursor is Tetrakis(dimethylamido)titanium: Ti(NMe₂)₄ and the oxide film is TiO₂.

19. The method of claim 1, comprising a preliminary step of forming a nanostructured pattern prior to the depositing, and after the oxide film is formed, removing the nanostructured pattern to leave the oxide film as an inverted, reduced dimension pattern.

20. The method of claim 19, wherein the nanostructured pattern comprises a close-packed monolayer of polystyrene spheres.

21. The method of claim 1, wherein the substrate comprises a silicon substrate.

22. The method of claim 1, wherein the substrate comprises a PET (polyethylene terephthalate) or other polymer substrate.

23. The method of claim 1, wherein the directing is conducted in an N₂ atmosphere at atmospheric pressure.

24. The method of claim 1, wherein the VUV radiation comprises photons having energies exceeding the energy of any chemical bond precursor.

25. The method of claim 1, wherein the liquid-phase precursor comprises a mixture of two or more liquid-phase precursors.

26. The method of claim 1, wherein a gas or vapor is bubbled through the liquid-phase precursor and subsequently delivered to a substrate.

27. The method of claim 26, wherein the radiation comprises VUV radiation of two wavelengths and two energies selected to break a bond in a first one of the two liquid-phase precursors and a bond in a second one of the two liquid-phase precursors.

28. The method of claim 1, wherein the depositing and distributing comprise spraying the liquid-phase oxide precursor outside of a deposition reactor onto a large area substrate or an object, and the directing radiation is conducted outside of the deposition reactor.

29. The method of claim 1, wherein the liquid-phase precursor comprises nano or microparticles.

30. The method of claim 1, wherein the liquid-phase precursor comprises quantum dots, graphene, or carbon nanotubes.

31. The method of claim 1, wherein the liquid-phase precursor is applied to a substrate so as to result in a sinusoidally-varying surface in the deposited oxide film.

32. The method of claim 31, comprising depositing an optically- or electrically-active thin film, such as GaN, Ga₂O₃, Si, Ge, or GaAs, onto the oxide or other dielectric film.

33. The method of claim 1, comprising a preliminary step of creating a patterned mask on the surface, wherein the depositing deposits the liquid-phase precursor into the patterned mask, and removing the mask after the oxide film is deposited, wherein the masking and depositing steps are repeated so as to fabricate air-bridges and step-profile structures.
